(19) United States
(12) Patent Application Publication
(10) Pub. No.: US 2006/0038267 A1
(43) Pub. Date: Feb. 23, 2006

(54) Display device with characteristic data stored therein

(75) Inventor: Hyun-Sang Cho, Suwon-si (KR)

Correspondence Address: DLA PIPER RUDNICK GRAY CARY US, LLP, 2000 UNIVERSITY AVENUE, E. PALO ALTO, CA, 94303-2248, US

(73) Assignee: Samsung Electronics Co., Ltd.

(21) Appl. No.: 11/177,159

(22) Filed: Jul. 7, 2005

(30) Foreign Application Priority Data
Aug. 20, 2004 (KR) 10-2004-0065840

(51) Int. Cl. H01L 23/02

(52) U.S. Cl. 257/678; 257/E27.132

(57) ABSTRACT

A method of manufacturing a display device is presented. The method includes mounting the memory on the printed circuit board (PCB) and writing the characteristic data in the memory. The characteristic data, which is data that is specific to a display device having a particular specification, allows an operator to verify that the correct characteristic data is being used for the display device type, size, etc. By mounting the memory on the PCB before the characteristic data is written in the memory but after the characteristic data is written in the PCB test procedure, the method allows the display device to be manufactured with fewer number of workers and fewer steps in the manufacturing process. A display device made using this method is also presented.

### RELATED APPLICATION

This application claims priority from Korean Patent Application No. 10-2004-0065840 filed on Aug. 20, 2004, the content of which is incorporated by reference herein in its entirety.

### BACKGROUND OF THE INVENTION

(a) Field of the Invention

The present invention relates to a display device and a manufacturing method thereof.

(b) Description of Related Art

Recently, flat panel displays such as organic light emitting displays (“OLEDs”), plasma display panels (“PDPs”) and liquid crystal displays (“LCDs”) have been widely used in various applications instead of heavy and large cathode ray tubes (“CRTs”).

PDPs are devices that display characters or images using plasma generated by a gas discharge. OLEDs are devices that display characters or images using electric field light-emission of specific organics or high molecules. LCDs are devices that display desired images by applying electric field to a liquid crystal layer between two panels and regulating the strength of the electric field to adjust the transmittance of light passing through the liquid crystal layer.

Among the flat panel displays, the LCD and the OLED each includes a panel assembly with pixels that have switching elements and display signal lines, a gate driver providing a gate signal for gate lines of the display signal lines to turn on/off the switching elements, a data driver providing a data signal for data lines of the display signal lines to apply a data voltage to the pixel via the turned-on switching elements, and a signal controller controlling the above-described elements. The signal controller is mounted on a printed circuit board (PCB), and the gate driver and the data driver are mounted on a flexible printed circuit film (FPC) as integrated circuits.

Such display devices begin to be popularized for television sets and an increasing number of other applications. Since the display devices for the television sets are often used for a long time each time under a variety of conditions, they have to be able to actively maintain their characteristics regardless of the ambient conditions. For example, the LCD may optimize the response speed to variations in the ambient temperature by storing data in a memory in advance. The LCD may also adjust the control signals of the signal controller according to the ambient temperature in order to optimize the image quality.

In this case, the data (hereinafter, referred to as “characteristic data”) related to such operations is stored in a memory such as an electrically erasable and programmable read only memory (EEPROM), which is typically mounted on the PCB together with the signal controller.

The memory is mounted on the PCB using a surface mounting technique after the characteristic data has been stored therein by using data writer (e.g., a ROM writer) and after the memory has been arranged in a tray.

However, when the characteristic data are stored in the EEPROM, there is no way of checking if wrong data are stored therein. For example, if characteristic data for a 26-inch display device are erroneously stored in the EEPROM instead of that for a 32-inch display device, an operator has no way of knowing this. The worker can only confirm whether the data are stored therein correctly, but he cannot check the correctness of the data because the characteristic data cannot be read with human eyes.

Another disadvantage of the current process order is that the data is stored in the memory by a worker using the ROM writer, and then, in a separate manufacturing plant, the memory is equipped and mounted on the PCB. This increases the number of workers and manufacturing cost.

### SUMMARY OF THE INVENTION

The present invention provides a display device and a manufacturing method thereof capable of easily confirming whether right characteristic data are stored and increasing productivity.

A manufacturing method of a display device having a panel assembly with pixels, wherein each of the pixels includes a switching element, gate lines, and data lines; a gate driver applying a gate signal to the switching elements; a data driver applying a data signal to the data lines; a signal controller generating control signals for controlling the gate driver and the data driver; and a memory storing characteristic data, wherein the signal controller and the memory are located on a printed circuit board that is connected to the panel assembly. The method includes mounting the memory on the printed circuit board and writing the characteristic data in the memory.

The characteristic data may include a product code datum that is specific to a display device.

The method may further include displaying the product code datum; and checking whether the product code datum matches the particular specification of the display device.

The manufacturing method of the display device may further include writing new characteristic data in the memory after erasing the characteristic data, if the characteristic data does not match a specification of the display device.

The manufacturing method of the display device may further include testing the printed circuit board after mounting the memory thereon.

The memory may be an EEPROM.

The writing of the characteristic data in the memory may be performed using a jig for a printed circuit board function test.

The memory is preferably disconnected from the signal controller after the characteristic data is written in the memory.

A display device is provided, which include: a panel assembly having pixels, wherein each of the pixels includes a switching element, gate lines, and data lines; a gate driver applying a gate signal to the switching elements; a data driver applying a data signal to the data lines; a signal controller generating control signals for controlling the gate driver and the data driver; a memory storing characteristic data; and a switching unit connected between the memory and the signal controller, wherein the signal controller, the memory, and the switching unit are located on a printed circuit board connected to the panel assembly.

The characteristic data are preferably written in the memory via test points located between the memory and the switching unit.

The switching unit is preferably in an off state when the characteristic data are written in the memory.

The memory may be an EEPROM.

### BRIEF DESCRIPTION OF THE DRAWINGS

The present invention will become more apparent by describing preferred embodiments thereof in detail with reference to the accompanying drawings in which:

FIG. 1 is a block diagram of a display device according to an exemplary embodiment of the present invention;

FIG. 2 illustrates a structure and an equivalent circuit diagram of a pixel of a liquid crystal display (LCD) according to an exemplary embodiment of the present invention;

FIG. 3 is a schematic view of a display device according to an exemplary embodiment of the present invention;

FIG. 4 is a flow chart to illustrate a manufacturing method of a display device according to an exemplary embodiment of the present invention; and

FIG. 5 is a block diagram of a printed circuit board (PCB) for a display device according to an exemplary embodiment of the present invention.

### DETAILED DESCRIPTION OF EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein.

In the drawings, the thickness of layers and regions are exaggerated for clarity. Like numerals refer to like elements throughout. It will be understood that when an element such as a layer, film, region, substrate or panel is referred to as being “on” another element, it can be directly on the other element or intervening elements may also be present. In contrast, when an element is referred to as being “directly on” another element, there are no intervening elements present.

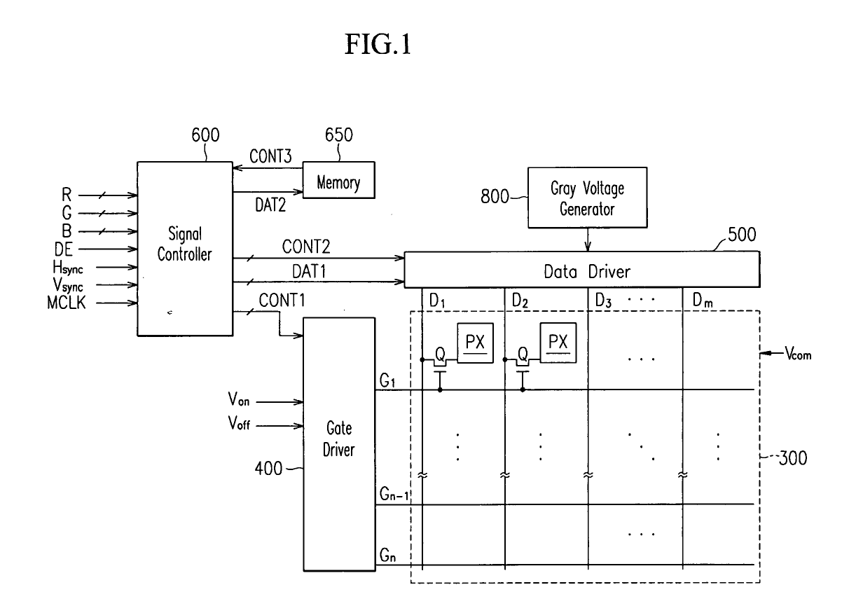

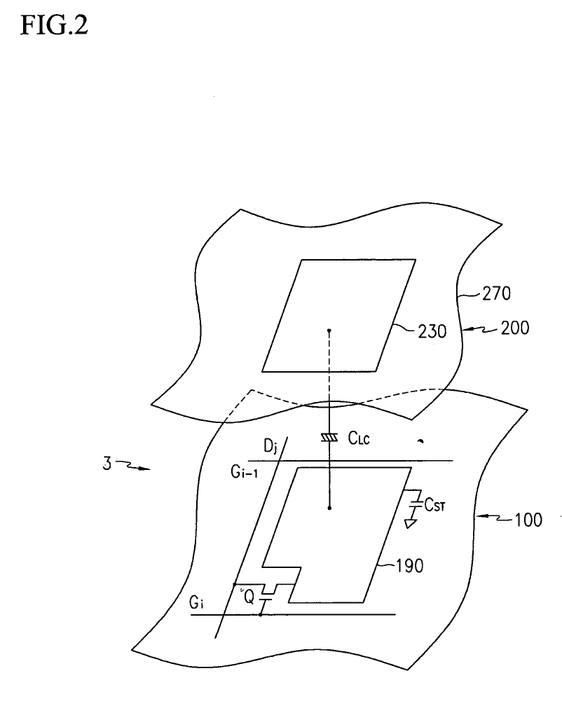

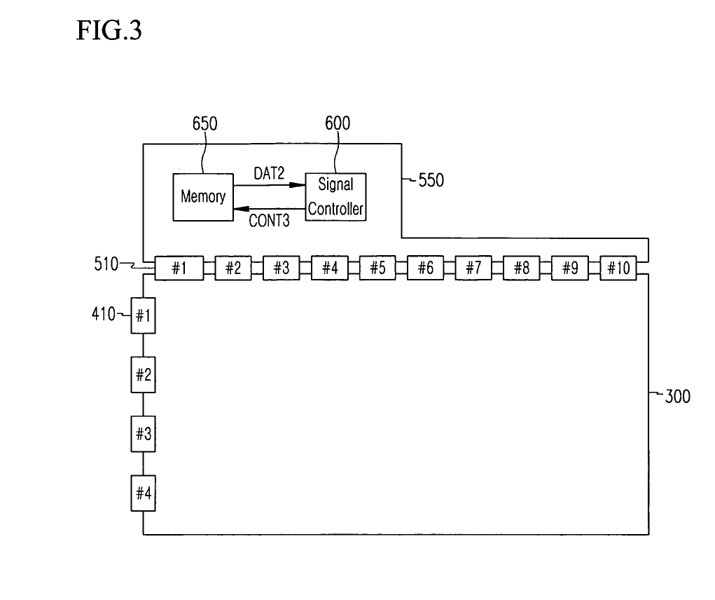

FIG. 1 is a block diagram of an LCD according to an embodiment of the present invention, and FIG. 2 is an equivalent circuit diagram of a pixel of an LCD according to an embodiment of the present invention, and FIG. 3 is a schematic view of a display device according to an exemplary embodiment of the present invention.

Referring to FIG. 1, a display device according to an exemplary embodiment of the present invention includes a panel assembly 300, a gate driver 400 and a data driver 500 connected thereto, a gray voltage generator 800 connected to the data driver 500, and a memory 650. A signal controller 600 controls the above-described elements.

The panel assembly 300 includes a plurality of display signal lines G₁-Gₙ and D₁-Dₘ and a plurality of pixels connected to the display signal lines G₁-Gₙ and D₁-Dₘ and arranged substantially in a matrix structure. The panel assembly 300 includes a lower panel 100 and an upper panel 200.

The display signal lines G₁-Gₙ and D₁-Dₘ are provided on the lower panel 100 and include gate lines G₁-Gₙ transmitting gate signals (called scanning signals) and data lines D₁-Dₘ transmitting data signals. The gate lines G₁-Gₙ extend substantially in a first direction and are substantially parallel to each other, while the data lines D₁-Dₘ extend substantially in a second direction that is perpendicular to the first direction. The data lines D₁-Dₘ are substantially parallel to each other.

Each pixel includes a switching element Q connected to one of the gate lines G₁-Gₙ and one of the data lines D₁-Dₘ, and pixel circuits PX connected to the switching element Q.

The switching element Q is provided on the lower panel 100 and has three terminals: a control terminal connected to one of the gate lines G₁-Gₙ; an input terminal connected to one of the data lines D₁-Dₘ; and an output terminal connected to the pixel circuit PX.

In active matrix type LCDs, which are an example of a flat panel display device, the panel assembly 300 includes the lower panel 100, the upper panel 200, a liquid crystal (LC) layer 3 disposed between the lower and upper panels 100 and 200, and the display signal lines G₁-Gₙ and D₁-Dₘ and the switching elements Q are provided on the lower panel 100. Each pixel circuit PX includes an LC capacitor C_{LC} and a storage capacitor C_{ST} that are connected in parallel with the switching element Q. The storage capacitor C_{ST} may be omitted if the storage capacitor C_{ST} is not needed.

The LC capacitor C_{LC} includes a pixel electrode 190 on the lower panel 100, a common electrode 270 on the upper panel 200, and the LC layer 3 as a dielectric between the pixel and common electrodes 190 and 270. The pixel electrode 190 is connected to the switching element Q, and the common electrode 270 covers the entire surface of the upper panel 200 and is supplied with a common voltage Vcom. Alternatively, both the pixel electrode 190 and the common electrode 270, which have shapes of bars or stripes, are provided on the lower panel 100.

The storage capacitor C_{ST} is an auxiliary capacitor for the LC capacitor C_{LC}. The storage capacitor C_{ST} includes the pixel electrode 190 and a separate signal line (not shown), which is provided on the lower panel 100 and overlaps the pixel electrode 190 with an insulator disposed between the pixel electrode 190 and the separate signal line. The storage capacitor C_{ST} is supplied with a predetermined voltage such as the common voltage Vcom. Alternatively, the storage capacitor C_{ST} includes the pixel electrode 190 and an adjacent gate line called a previous gate line, which overlaps the pixel electrode 190 with an insulator disposed between the pixel electrode 190 and the previous gate line.

For a color display, each pixel uniquely represents one of three primary colors such as red, green and blue (spatial division) or represents the three primary colors in time (temporal division), thereby obtaining a desired color. FIG. 2 shows an example of the spatial division in which each pixel includes a color filter 230 representing one of the three primary colors in an area of the upper panel 200 facing the pixel electrode 190. Alternatively, the color filter 230 is provided on or under the pixel electrode 190 on the lower panel 100.

A pair of polarizers (not shown) for polarizing light are attached on the outer surfaces of the lower and upper panels 100 and 200 of the panel assembly 300.

Referring back to FIG. 1, a gray voltage generator 800 generates one set or two sets of gray voltages related to a transmittance of the pixels. When two sets of the gray voltages are generated, the gray voltages in one set have a positive polarity with respect to the common voltage Vcom, while the gray voltages in the other set have a negative polarity with respect to the common voltage Vcom.

The gate driver 400 synthesizes the gate-on voltage Von and the gate-off voltage Voff to generate gate signals for application to the gate lines G₁-Gₙ. The gate driver is a shift register, which includes a plurality of stages in a line.

The data driver 500 is connected to the data lines D₁-Dₘ of the panel assembly 300 and applies data voltages selected from the gray voltages supplied from the gray voltage generator 800 to the data lines D₁-Dₘ.

The memory 650 stores a variety of characteristic data required for the display device and outputs data adjusted for ambient conditions.

Such data includes, for example, adaptive color capture (ACC) data, dynamic capacitance compensation (DCC) data, control signal data for the data driver 500 and the gate driver 400, and so on.

The ACC data is data for fine correction for each red, green and blue data in order to minimize a variation of color coordinate between grays. The DCC data is a look-up table (LUT) data for determining the maximum value of a response speed between grays, and, recently, eight to twelve LUT data are provided. The control signal data for the data driver 500 and the gate driver 400 are data for adjusting widths and orders of the control signals.

The signal controller 600 controls the gate driver 400 and the data driver 500. As shown in FIG. 3, the signal controller 600 and the memory 650 are mounted on the PCB 550, and the data driver 500 and the gate driver 400 are mounted on flexible printed circuit films (FPCs) 510 and 410 in a COF (chip on film) type as separate chips, respectively.

Now, the operation of the display device will be described in detail referring to FIG. 1.

The signal controller 600 is supplied with image signals R, G and B and input control signals controlling the display of the image signals R, G and B. The input control signals include, for example, a vertical synchronization signal Vsync, a horizontal synchronization signal Hsync, a main clock MCLK, and a data enable signal DE, from an external graphic controller (not shown). After generating gate control signals CONT1 and data control signals CONT2 and processing the image signals R, G and B suitable for the operation of the panel assembly 300 in response to the input control signals, the signal controller 600 provides the gate control signals CONT1 to the gate drivers 400L and 400R, and the processed image signals DAT and the data control signals CONT2 to the data driver 500. Moreover, the signal controller 600 provides memory control signals CONT3 to the memory 650 in accordance with ambient circumstance such as a temperature.

The gate control signals CONT1 include a vertical synchronization start signal STV for informing the gate driver of a start of a frame, a gate clock signal CPV for controlling an output time of the gate-on voltage Von, and an output enable signal OE for defining a width of the gate-on voltage Von.

The data control signals CONT2 include a horizontal synchronization start signal STH for informing the data driver 500 of a start of a horizontal period, a load signal LOAD or TP for instructing the data driver 500 to apply the appropriate data voltages to the data lines D₁-Dₘ, and a data clock signal HCLK. The data control signals CONT2 may further include an inversion control signal RVS for reversing the polarity of the data voltages (with respect to the common voltage Vcom).

The memory control signals CONT3 include an enable signal for activating the memory 650 and a disable signal for inactivating the memory 650. The enable signal may be finely divided to ensure that the memory 650 outputs the desired version of the above-described characteristic data.

The data driver 500 receives the processed image signals DAT1 for a pixel row from the signal controller 600 and converts the processed image signals DAT1 into the analogue data voltages selected from the gray voltages supplied from the gray voltage generator 800 in response to the data control signals CONT2 from the signal controller 600. Responsive to the gate control signals CONT1 from the signal controller 600, the gate driver 400 applies the gate-on voltage Von to the gate lines G₁-Gₙ, thereby turning on the switching elements Q connected to the gate lines G₁-Gₙ. The data voltages in turn are supplied to corresponding pixels via the turned-on switching elements Q.

The memory 650 provides required characteristic data DAT2 to the signal controller 600 in response to the memory control signals CONT3, and the signal controller 600 drives the display device optimized using such characteristic data.

The difference between the data voltage and the common voltage Vcom applied to a pixel is expressed as a charged voltage of the LC capacitor C_{LC}, i.e., a pixel voltage. The liquid crystal molecules have orientations depending on a magnitude of the pixel voltage and the orientations determine a polarization of light passing through the LC capacitor C_{LC}. The polarizers convert light polarization into light transmittance.

The data driver 500 applies the data voltages to corresponding data lines D₁-Dₘ for a turn-on time of the switching elements Q (which is called “one horizontal period” or “1H” and equals one period of the horizontal synchronization signal Hsync, the data enable signal DE, and the gate clock signal CPV).

By repeating the above described procedure, all gate lines G₁-Gₙ are sequentially supplied with the gate-on voltage Von during a frame, thereby applying the data voltages to all pixels. In case of the LCD shown in FIG. 2, when a next frame starts after finishing one frame, the inversion control signal RVS applied to the data driver 500 is controlled such that a polarity of the data voltages is reversed (“frame inversion”). The inversion control signal RVS may be controlled such that the polarity of the data voltages flowing in a data line in one frame are reversed (e.g.: “row inversion”, “dot inversion”), or the polarity of the data voltages in one packet are reversed (e.g.:“column inversion”, “dot inversion”).

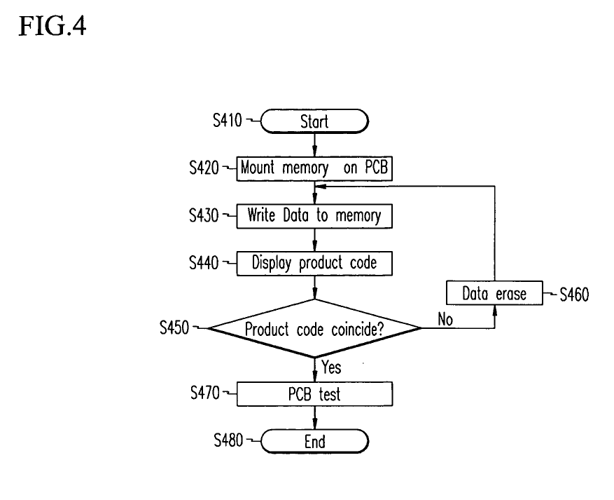

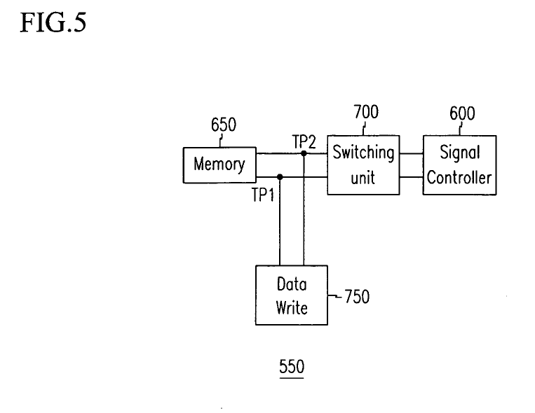

Now, a display device and a manufacturing method thereof will be described in detail with reference to FIGS. 4 and 5.

FIG. 4 is a flow chart illustrating a manufacturing method of the display device according to an exemplary embodiment of the present invention, and FIG. 5 is a block diagram of a PCB for a display device according to an exemplary embodiment of the present invention.

First, the memory 650 is mounted on the PCB 550 (S420).

Subsequently, the characteristic data DAT2 are written in the memory 650 mounted on the PCB 550 (S430). In this case, the characteristic data DAT2 include not only the above-described ACC and DCC data but also the product code data. The product code data are data that is specific to the display device specification such as measurements of manufactured display devices, (e.g., 32 inches, 37 inches). The storage of the characteristic data DAT2 is performed using a jig for PCB function test (PFT).

Next, the product code data written in the previous step are displayed on a separate monitor (S440). It is checked (e.g., by an operator) whether the product code data matches the product (S450). If there is no match, the written data in the memory 650 are erased (S460) and the matching characteristic data are rewritten (S430). If there is a match, a PCB test is performed (S470).

In this way, the correctness of the data can be secured since a worker checks whether a product code on a work sheet matches the product code in the characteristic data after writing the characteristic data. Unlike in the conventional process, a separate worker and a procedure are not required since the memory 650 is directly mounted on the PCB 550 and the jig used for the existing PCB test procedure is used as is.

As shown in FIG. 5, a PCB 550 according to an exemplary embodiment of the present invention includes a memory 650, a switching unit 700, and a signal controller 600. A data writer 750 is used to write characteristic data in the memory 650, which is the ROM writer described above.

The memory 650, the switching unit 700 and the signal controller 600 are integrated circuits with a plurality of pins, only two of which are shown in FIG. 5. Jigs are connected to two terminals of the data writer 750, respectively.

First, data is written in the memory 650 using the data writer 750. In this case, the jigs are contacted with two test points TP1 and TP2. Then, the switching unit 700 is in an off state, and thus the memory is disconnected from the signal controller 600 while it is connected to the data writer 750.

When writing of the characteristic data DAT2 is completed, the data writer 750 is removed, and then the switching unit 700 is in an on state. Thus, the signal controller 600 is connected to the memory 650.

Accordingly, this prevents the master/slave function of the signal controller 600 and the memory 650 from abnormally operating when the data are directly written in the memory 650 without switching unit 700.

In the meantime, writing of the data DAT2 is easy since the jigs for the PFT are in contact with the test points TP1 and TP2 instead of the pins of the memory 650.

As described above, since the memory 650 is mounted on the PCB 650 in the state where the characteristic data DAT2 is not written in the memory 650 but the characteristic data DAT2 is written in the PCB test procedure, the number of workers and the manufacturing processes are not added. Also, the correctness of the data DAT2 is secured by displaying and confirming the data DAT2 through a separate monitor.

While the present invention has been described in detail with reference to the preferred embodiments, it is to be understood that the invention is not limited to the disclosed embodiments. On the contrary, the invention is intended to cover various modifications and equivalent arrangements included within the sprit and scope of the appended claims.

What is claimed is:

1. A method of manufacturing a display device having a panel assembly with pixels, wherein each of the pixels includes a switching element, gate lines and data lines, a gate driver applying a gate signal to the switching element, a data driver applying a data signal to the data lines, a signal controller generating control signals for controlling the gate driver and the data driver, and a memory storing characteristic data, wherein the signal controller and the memory are located on a printed circuit board that is connected to the panel assembly, the method comprising:
mounting the memory on the printed circuit board; and
writing the characteristic data in the memory.

2. The method of claim 1, wherein the characteristic data comprises a product code datum for checking a specific specification of the display device.

3. The method of claim 2, wherein the display device displays the product code datum that is specific to a display device.

4. The method of claim 3 further comprising writing new characteristic data in the memory after erasing the characteristic data if the characteristic data does not match a specification of the display device.

5. The method of claim 1 further comprising testing the printed circuit board after mounting the memory thereon.

6. The method of claim 1, wherein the memory is an EEPROM.

7. The method of claim 1 further comprising writing the characteristic data in the memory by using a jig for a printed circuit board function test.

8. The method of claim 7, wherein the memory is disconnected from the signal controller after the characteristic data is written in the memory.

9. A display device comprising:
a panel assembly having pixels, wherein each of the pixels includes a switching element, gate lines and data lines;
a gate driver applying a gate signal to the switching element;
a data driver applying a data signal to the data lines;
a signal controller generating control signals for controlling the gate driver and the data driver;
a memory storing characteristic data; and
a switching unit connected between the memory and the signal controller, wherein the signal controller, the memory, and the switching unit are located on a printed circuit board connected to the panel assembly.

10. The display device of claim 9, wherein the characteristic data are written in the memory via test points located between the memory and the switching unit.

11. The display device of claim 10, wherein the switching unit is in an off state when the characteristic data are written in the memory.

12. The display device of claim 9, wherein the memory is an EEPROM.
